(19) United States
(12) Patent Application Publication
(10) Pub. No.: US 2026/0023965 A1
(43) Pub. Date: Jan. 22, 2026

(54) OPTOELECTRONIC MODULE AND OPTICAL ARTIFICIAL NEURAL NETWORK SYSTEM INCLUDING THE SAME

(71) Applicant: Electronics and Telecommunications Research Institute, Daejeon (KR)

(72) Inventors: Suntak PARK, Daejeon (KR); Jin Hwa GENE, Daejeon (KR)

(21) Appl. No.: 19/218,160

(22) Filed: May 23, 2025

(30) Foreign Application Priority Data
Jul. 16, 2024 (KR) 10-2024-0093941

(51) Int. Cl. G06N 3/067; H01S 5/183; H10F 39/10; H10F 55/15

(52) U.S. Cl. CPC G06N 3/0675; H10F 55/15; H01S 5/183; H10F 39/10

(57) ABSTRACT

An optoelectronic module according to an embodiment of the present invention includes a photodetector that receives an input light and converts the input light to generate a first current, an electronic element that amplifies the first current to generate a second current, and a light source element that converts the second current to generate an output light. The output light has characteristics of a result of performing a non-linear computation of an optical artificial neural network.

### CROSS-REFERENCE TO RELATED APPLICATIONS

This application claims priority under 35 U.S.C. § 119 to Korean Patent Application No. 10-2024-0093941 filed on Jul. 16, 2024, in the Korean Intellectual Property Office, the disclosures of which are incorporated by reference herein in their entireties.

### BACKGROUND

Artificial Neural Network is a machine learning technique that process information in a manner similar to the principles in which the human brain processes and learns information. With the development of computer hardware, the capability to process big data is improved, and a deep learning algorithm develops. This allows the artificial neural network technology to be rapidly expanded and applied to various fields such as voice recognition, pattern recognition, natural language processing, and medical data analysis.

The artificial neural network includes an input layer, a hidden layer, and an output layer, each of which is composed of nodes, and the nodes process signal information like neurons. The nodes of the hidden layer add weights to signals received from the nodes of the input layer and perform non-linear transformation on the addition results, and the outputs of the nodes of the hidden layer are transferred to the output layer such that a final output signal is generated.

The signal processing process of the artificial neural network is similar to that of a neuron, and the artificial neural network may include only one hidden layer or may include a plurality of hidden layers. An artificial neural network including a plurality of hidden layers is referred to as a deep neural network (or a deep learning artificial neural network), and learning using the deep neural network is referred to as deep learning.

The deep neural network using deep learning requires a large amount of computation to optimize weights as the number of hidden layers increases. In particular, as the number of neurons and hidden layers increases, the amount of computation increases exponentially, in this case, computation through a semiconductor-based electrical computer becomes more complex and requires greater power consumption, eventually reaching technical limitations.

To overcome the above limitations, optical neural computing technologies having an excellent characteristic in parallel processing have been proposed. The optical computing technologies may make it possible to process massive amounts of computation at high speed with small power consumption, inherently as well as efficient parallel calculations.

A computation process of the optical neural computing consists of linear computation and non-linear computation. The linear computation can be implemented optically using an optical device or the like. However, the non-linear computation uses optical non-linearity of a material, which leads to the issue of low accuracy in the non-linear computation. Therefore, an optical method capable of achieving the non-linear computation with high accuracy is required.

### SUMMARY

Embodiments of the present disclosure described herein relate to an optical artificial neural network system, and more particularly, to an optoelectronic module configured to perform non-linear computation of the optical artificial neural network and an optical artificial neural network system including the same.

An object of the present disclosure is to provide an optoelectronic module configured to perform non-linear computation of an optical artificial neural network with high accuracy, and an optical artificial neural net system including the same.

According to an embodiment of the present disclosure, a optoelectronic module includes a photodetector that receives input light and converts the input light to generate a first current, an electronic element that amplifies the first current to generate a second current, and a light source element that converts the second current to generate output light. The output light has characteristics of a result of performing a non-linear computation of an optical artificial neural network.

According to an embodiment, the non-linear computation includes a computation for applying an activation function. The light source element generates the output light based on the second current and a threshold current of the light source element.

According to an embodiment, the activation function is a Relu function. The light source element oscillates such that intensity of the output light is proportional to intensity of the second current when the second current is greater than the threshold current.

According to an embodiment, the optoelectronic module further includes a resistance that determines a maximum value of intensity of the output light. The activation function is a Sigmoid function. The light source element oscillates such that the output light has the intensity corresponding to the maximum value when the second current is greater than the threshold current.

According to an embodiment, the photodetector includes a photodiode. The electronic element includes at least one of a transistor and an operational amplifier. The light source element includes a surface emitting laser.

According to an embodiment, the optoelectronic module includes a unit cell array including a plurality of unit cells. Each of the plurality of unit cells includes the photodetector, the electronic element, and the light source element.

According to an embodiment, each of the plurality of unit cells further includes a resistance that determines a maximum value of intensity of the output light.

According to an embodiment, the optoelectronic module further includes a photodetector array in which the photodetector is disposed in an array form, and a light source array in which the light source element is disposed in the array form.

According to an embodiment, the photodetector array and the light source array are disposed such that the input light and the output light propagate in the same direction.

According to an embodiment, the optoelectronic module includes a first PCB substrate including the photodetector array, a second PCB substrate including the light source array and the electronic element, and a connector connecting the first PCB substrate and the second PCB substrate.

According to an embodiment, the photodetector array is disposed on a first side of the PCB substrate. The light source array is disposed on the second side of the PCB substrate.

According to an embodiment, the photodetector array and the light source array are disposed such that the input light and the output light propagate in opposite directions.

According to an embodiment, the photodetector array and the light source array are disposed on a first side of the PCB substrate.

According to an embodiment of the present disclosure, an optical artificial neural network system includes a linear computation unit that receives an input light including input data and performs a linear computation on the input data to generate a first processed light, and a non-linear computation unit that performs a non-linear computation on data included in the first processed light to generate an output light. The output light has characteristics of a result of a computation for applying an activation function. The non-linear computation unit includes a photodetector that converts the first processed light to generate a first current, an electronic element that amplifies the first current to generate a second current, and a light source element that converts the second current to generate the output light.

According to an embodiment, the light source element generates the output light based on the second current and the threshold current of the light source element.

According to an embodiment, the activation function is a Relu function. The light source element oscillates such that intensity of the output light is proportional to intensity of the second current when the second current is greater than the threshold current.

According to an embodiment, the non-linear computation unit further includes a resistance that determines a maximum value of intensity of the output light. The activation function is a Sigmoid function. The light source element oscillates such that the output light has the intensity corresponding to the maximum value when the second current is greater than the threshold current.

According to an embodiment, the photodetector includes a photodiode. The electronic element includes at least one of a transistor and an operational amplifier. The light source element includes a surface emitting laser.

According to an embodiment, the non-linear computation unit includes a unit cell array including a plurality of unit cells. Each of the plurality of unit cells includes the photodetector, the electronic element, and the light source element.

According to an embodiment, the non-linear computation unit includes a photodetector array in which the photodetector is disposed in an array form, and a light source array in which the light source element is disposed in the array form.

### BRIEF DESCRIPTION OF THE FIGURES

The above and other objects and features of the present disclosure will become apparent by describing in detail embodiments thereof with reference to the accompanying drawings.

FIG. 1 illustrates an information processing process of an optical artificial neural network.

FIGS. 2A and 2B illustrate graphs of output data.

FIG. 3 illustrates an example of an optical artificial neural network system according to an embodiment of the present disclosure.

FIG. 4 illustrates an optoelectronic module according to an embodiment of the disclosure.

FIG. 5 illustrates a schematic diagram of an optoelectronic module according to an embodiment of the present disclosure.

FIG. 6 illustrates a graph of the output optical signal output from the optoelectronic module of FIG. 5.

FIG. 7 illustrates a schematic diagram of an optoelectronic module according to an embodiment of the present disclosure.

FIG. 8 illustrates a graph of the output optical signal output from the optoelectronic module of FIG. 7.

FIG. 9 illustrates a multi-channel optoelectronic module according to an embodiment of the present disclosure.

FIG. 10 illustrates a multi-channel optoelectronic module according to an embodiment of the present disclosure.

FIG. 11 illustrates a multi-channel optoelectronic module according to an embodiment of the present disclosure.

FIG. 12 illustrates a multi-channel optoelectronic module according to an embodiment of the present disclosure.

### DETAILED DESCRIPTION

Hereinafter, embodiments of the present disclosure may be described in detail and clearly to such an extent that an ordinary one in the art easily implements the present disclosure.

Components that are described in the detailed description with reference to the terms “unit”, “module”, “block”, “˜er or ˜or”, etc. and function blocks illustrated in drawings will be implemented with software, hardware, or a combination thereof. For example, the software may be a machine code, firmware, an embedded code, and application software. For example, the hardware may include an electrical circuit, an electronic circuit, a processor, a computer, an integrated circuit, integrated circuit cores, a pressure sensor, an inertial sensor, a microelectromechanical system (MEMS), a passive element, or a combination thereof.

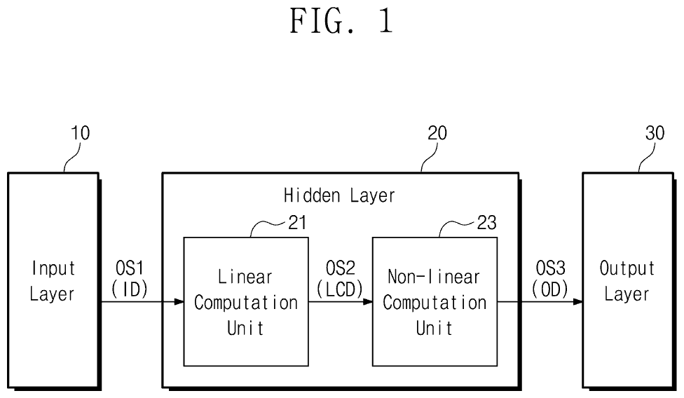

FIG. 1 illustrates an information processing process of an optical artificial neural network. Referring to FIG. 1, the optical artificial neural network may include an input layer 10, a hidden layer 20, and an output layer 30.

The input layer 10 may include a plurality of nodes. Each of the plurality of nodes may transmit input data ID to the hidden layer 20.

The hidden layer 20 may perform linear computation and non-linear computation on the input data ID received from the input layer 10 to generate output data OD. For example, the linear computation unit 21 of the hidden layer 20 may perform the linear computation on the input data ID received from the input layer 10. The non-linear computation unit 23 of the hidden layer 20 may perform the non-linear computation on linearly computed data LCD to generate the output data OD to which an activation function is applied or the output data OD having characteristics of the activation function.

In some embodiments, the linear computation may include a weight computation. For example, the hidden layer 20 may include a plurality of nodes. The plurality of nodes of the hidden layer 20 may be respectively connected to the plurality of nodes of the input layer 10. The plurality of nodes of the hidden layer 20 may perform the linear computation to assign weights to the input data ID received from each of the plurality of nodes of input layer 10. However, the scope of the present disclosure is not limited thereto, and the linear computation unit 21 may perform various linear computations such as matrix computation and convolution computation, etc.

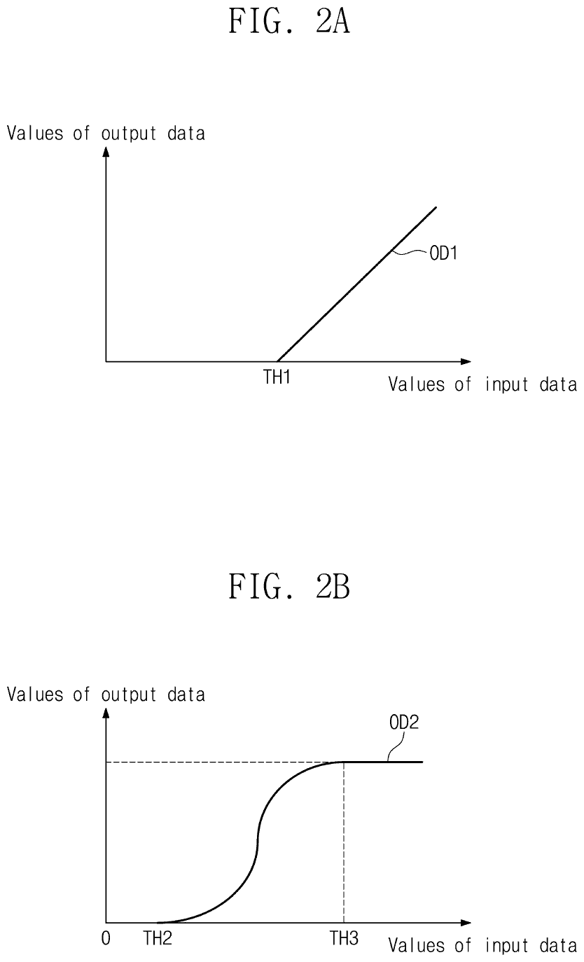

The hidden layer 20 may transmit the output data OD to the output layer 30. The output data OD with the activation function applied is described in more detail with reference to FIGS. 2A and 2B.

The output layer 30 may generate a prediction result based on the output data OD received from the hidden layer 20.

In FIG. 1, the optical artificial neural network is shown as including one hidden layer 20, but the optical artificial neural network may further include a plurality of hidden layers. The optical artificial neural network may learn the weight for the input data ID and continuously adjust a value of the weight based on computation of the plurality of hidden layers. Therefore, as the number of hidden layers increases, the accuracy of prediction of the optical artificial neural network may be improved.

In FIG. 1, the optical artificial neural network may transmit data by using an optical signal OS. For example, the input layer 10 may transmit a first optical signal OS1 including the input data ID to the linear computation unit 21, the linear computation unit 22 may transmit the second optical signal OS2 including the linearly computed data LCD to the non-linear computation unit 23, and the non-linear computation unit 23 may transmit the third optical signal OS3 including the output data OD to the output layer 30.

FIGS. 2A and 2B illustrate graphs of output data. In FIGS. 2A and 2B, the horizontal axis represents values of input data, and the vertical axis represents values of output data. In FIG. 2A, the input data may correspond to the linear computed data LCD of FIG. 1, and the first output data OD1 may correspond to the output data OD of FIG. 1. In FIG. 2B, the input data may correspond to the linear computed data LCD of FIG. 1, and the second output data OD2 may correspond to the output data OD of FIG. 1.

Referring to FIG. 2A, the first output data OD1 may have characteristics of a Relu function. For example, when the value of the input data is less than or equal to the first threshold TH1, the value of the first output data OD1 may be ‘0’. When the value of the input data exceeds the first threshold TH1, the value of the first output data OD1 may increase in proportion to the value of the input data. In some embodiments, the first threshold TH1 may be ‘0’.

Referring to FIG. 2B, the second output data OD2 may have characteristics of a Sigmoid function. For example, when the value of the input data is less than or equal to the second threshold TH2, the value of the second output data OD2 may be ‘0’. When the value of the input data exceeds the third threshold TH3, the value of the second output data OD2 may be a constant value (for example, ‘1’).

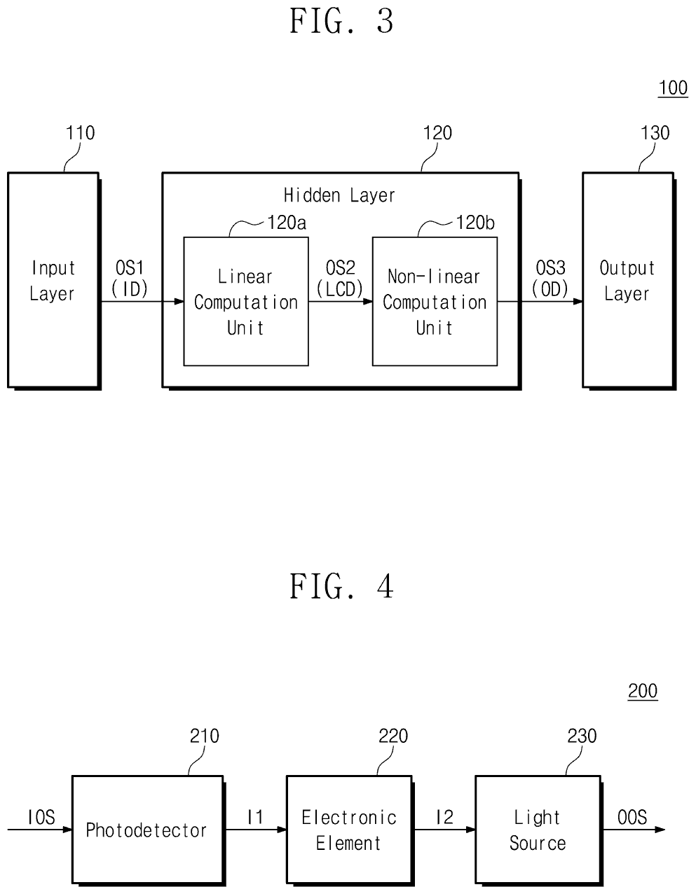

FIG. 3 illustrates an example of an optical artificial neural network system according to an embodiment of the present disclosure. Referring to FIG. 3, an optical artificial neural network system 100 may include an input unit 110, a hiding unit 120, and an output unit 130.

In FIG. 3, the optical artificial neural network system 100 may be configured to perform operations of the optical artificial neural network of FIG. 1. That is, the input unit 110 may perform an operation of the input layer 10 of FIG. 1, the hidden unit 120 may perform an operation of the hidden layer 20 of FIG. 1, and the output portion 130 may perform an operation of the output layer 30 of FIG. 1.

The input unit 110 may be configured to generate a first optical signal OS1. The first optical signal OS1 may comprise input data ID. The input unit 110 may transmit the first optical signal OS1 to a linear computation unit 120a of the hiding unit 120.

In some embodiments, a plurality of pixel regions corresponding to a plurality of nodes may be defined in the first optical signal OS1. Each of the plurality of pixel regions may include the input data ID corresponding thereto. For example, each of the plurality of pixel regions may store the input data ID by adjusting intensity of a received optical signal.

The linear computation unit 120a may receive the first optical signal OS1 from the input 110. The linear computation unit 120a may perform a linear computation on the input data ID included in the first optical signal OS1, to generate linearly computed data LCD. The linear computation unit 120a may transmit a second optical signal OS2 including the linearly computed data LCD to a non-linear computation unit 120a.

In some embodiments, the linear computation unit 120a may include an optical element configured to perform linear computation. For example, the linear computation unit 120a may include optoelectronic devices, such as a light modulator which include a plurality of pixels, or a lens and optoelectronic systems, which are implemented by a combination of the optoelectronic devices, such as a vector matrix multiplication (VMM) system and a 4F system.

The non-linear computation unit 120b may receive the second optical signal OS2 from the linear computation unit 120a. The non-linear computation unit 120b may perform a non-linear computation on the linearly computed data LCD included in the second optical signal OS2 to generate output data OD to which an activation function is applied or the output data OD having characteristics of the activation function. The non-linear computation unit 120b may transmit a third optical signal OS3 including the output data OD to the output unit 130. The non-linear computation unit 120b is described in more detail with reference to FIGS. 4-6B.

FIG. 4 illustrates an optoelectronic module according to an embodiment of the disclosure. In FIG. 4, an optoelectronic module 200 corresponds to the non-linear computation unit 120b of FIG. 3, an input optical signal IOS corresponds to the second optical signal OS2 of FIG. 3 and an output optical signal OOS may correspond to the third optical signal OS3 of FIG. 3.

The optoelectronic module 200 may include a photodetector 210, an electronic element 220, and a light source 230. The photodetector 210 may receive the input optical signal IOS. The photodetector 210 may convert the received input optical signal IOS into an electrical signal. For example, the photodetector 210 may convert the received input optical signal IOS to generate a first current I1.

The photodetector 210 can transmit the converted electrical signal to the electronic element 220. For example, the photodetector 210 may transmit the first current I1 to the electronic element 220.

In some embodiments, the photodetector 210 may be an element configured to convert an optical signal into an electrical signal. For example, the photodetector 210 may be a photo diode (PD). However, the scope of the present disclosure is not limited thereto.

The electronic element 220 may receive the electrical signal from the photodetector 210. The electronic element 220 may electrically process the received electrical signal. For example, the electronic element 220 may amplify the first current I1 received from the photodetector 210 to generate a second current I2.

The electronic element 220 may transmit the processed electrical signal to the light source 230. For example, the electronic element 220 may transmit the second current I2 to the light source 230.

In some embodiments, the electronic element 220 may be an element configured to amplify the received electrical signal. For example, the electronic element 220 may be a transistor or an operational amplifier. However, the scope of the present disclosure is not limited thereto.

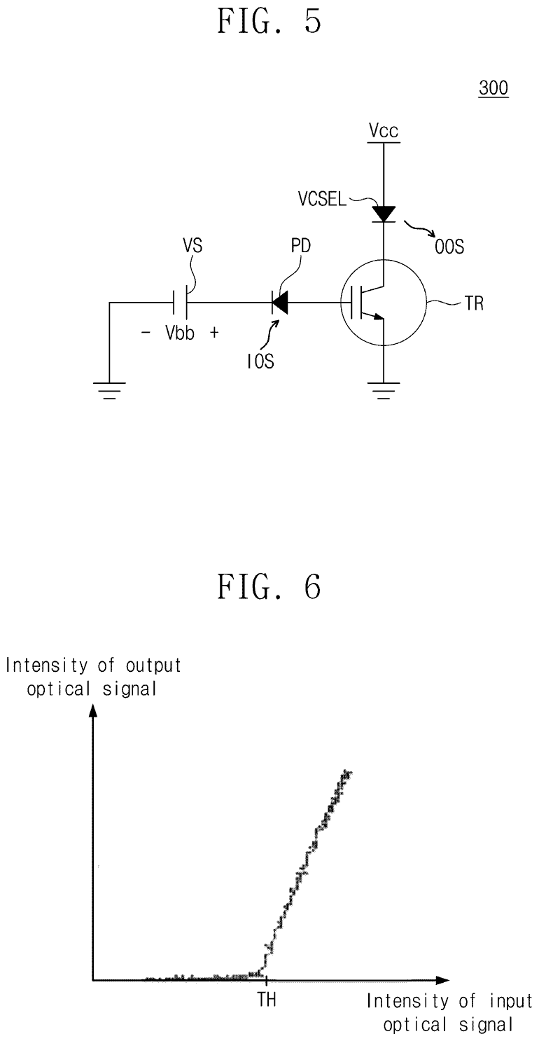

The light source 230 may receive the processed electrical signal from the electronic element 220. The light source 230 may convert the processed electrical signal into an optical signal. For example, the light source 230 may convert the second current I2 to generate an output optical signal OOS to which an activation function is applied or an output optical signal OOS having characteristics of the activation function. The light source 230 may output the output optical signal OOS. The output optical signal OOS is described in detail with reference to FIGS. 5A-6B.

The light source 230 may convert the electrical signal into the optical signal based on a threshold current. For example, if the second current I2 received from the electronic element 220 is less than the threshold current of the light source 230, the light source 230 may not oscillate. That is, intensity of the output optical signal OOS of the light source 230 may be ‘0’.

For example, if the second current I2 received from the electronic element 220 is greater than the threshold current of the light source 230, the light source 230 may oscillate to generate the output optical signal OOS in the form of the activation function.

In some embodiments, the light source 230 may be a light source element configured to convert an optical signal into an electrical signal. For example, the light source 230 may be one of a laser, a light emitting diode (LED), and a surface emitting laser (e.g., a vertical cavity surface emitting laser (VCSEL)). However, the scope of the present disclosure is not limited thereto.

In some embodiments, the optoelectronic module 200 may not amplify the electrical signal. For example, when intensity of the first current I1 output from the photodetector 210 exceeds a threshold value, the optoelectronic module 200 may not amplify the first current I2. Accordingly, the electronic element 220 may directly transmit the received first current I1 to the light source 230.

In some embodiments, the optoelectronic module 200 may be implemented as an electrical circuit or an electronic circuit.

Unlike shown in FIG. 4, in some embodiments, the optoelectronic module 200 may not include the electronic element 220. For example, when the photodetector 210 is configured to output the first current I1 exceeding threshold intensity, the optoelectronic module 200 may not include the electronic element 220.

Although not shown, the optoelectronic module 200 may further include a resistor that adjusts the intensity of the output optical signal OOS. For example, the optoelectronic module 200 may further include the resistor configured to determine a maximum intensity of the output optical signal OOS.

As described above, the optoelectronic module 200 may be configured to perform non-linear computation of the optical artificial neural network. The optoelectronic module 200 may output a non-linear optical signal based on a linear optical signal. For example, the optoelectronic module 200 may convert the linear optical signal into an electrical signal, process (e.g., amplify) the electrical signal, and convert the processed electrical signal to output the non-linear optical signal. The non-linear optical signal may have characteristics of an activation function and may be amplified in intensity compared to the linear optical signal. In this case, the characteristics of the activation function and an amplification factor of the intensity may be adjusted by means of the elements included in the optoelectronic module 200.

FIG. 5 illustrates a schematic diagram of an optoelectronic module according to an embodiment of the present disclosure. In FIG. 5, a photodiode PD, a transistor TR, and a surface emitting laser VCSEL may correspond to the photodetector 210, the electronic element 220, and the light source 230 of FIG. 4, respectively.

Referring to FIG. 5, an optoelectronic module 300 may include the photodiode PD, the transistor TR, and the surface emitting laser VCSEL.

The optoelectronic module 300 may operate based on a voltage Vbb applied from a voltage source VS to the photodiode PD and a voltage Vcc applied to the surface emitting laser VCSEL. In some embodiments, the voltage Vcc may be generated by an electronic circuit, such as a voltage generator located inside or outside the optoelectronic module 300. In some embodiments, the voltage Vcc may be generated from a voltage source located inside or outside the optoelectronic module 300.

The photodiode PD may convert an input optical signal IOS into a current that is an electrical signal, and output the current. The transistor TR may amplify the current output from the photodiode PD and output the amplified current. The surface emitting laser VCSEL may convert the amplified current output from the transistor TR into an output optical signal OOS, and output the output optical signal OOS.

In some embodiments, a wavelength of the input optical signal IOS may be ‘850’ nm. In some embodiments, the surface emitting laser VCSEL may be a surface emitting laser of ‘670’ nm. For example, a wavelength of the output optical signal OOS may be ‘670’ nm. However, the scope of the present disclosure is not limited thereto.

In some embodiments, the optoelectronic module 300 may operate based on a current (hereinafter referred to as a ‘transmission current’) transmitted to the surface emitting laser VCSEL based on the input optical signal IOS and a threshold current of the surface emitting laser VCSEL. For example, if the transmission current is less than the threshold current of the surface emitting laser VCSEL, the surface emitting Laser VCSEL may not oscillate. In this case, intensity of the output optical signal OOS may be ‘0’. If the transmission current is greater than the threshold current of the surface emitting laser VCSEL, the surface emitting Laser VCSEL may oscillate such that the intensity of the output optical signal IOS is proportional to intensity of the transmission current.

In some embodiments, the optoelectronic module 300 may operate based on the intensity of the input optical signal IOS and the threshold current of the surface emitting laser VCSEL. For example, when the intensity of the input optical signal IOS is less than or equal to a threshold value, the transmission current may be less than the threshold current of the surface emitting laser VCSEL. In this case, the surface emitting laser VCSEL may not oscillate, and the intensity of the output optical signal OOS may be ‘0’. If the intensity of the input optical signal IOS exceeds the threshold value, the transmission current may be greater than the threshold current of the surface emitting laser VCSEL. In this case, the surface emitting laser VCSEL may oscillate such that the intensity of the output optical signal IOS is proportional to the intensity of the input optical signal IOS, and the output optical signal OOS may have the form of a Relu function among the activation functions.

As described above, the optoelectronic module 300 may output the output optical signal OOS to which the Relu function of the activation functions is applied or the output optical signal OOS having the characteristics of the Relu function based on intensity of the transmission current or the input optical signal IOS. However, the scope of the present activation is not limited thereto, and the optoelectronic module 300 may output the output optical signal OOS having characteristics of various activation functions.

FIG. 6 illustrates a graph of the output optical signal output from the optoelectronic module of FIG. 5. In FIG. 6, a horizontal axis may represent intensity of an input optical signal IOS, and a vertical axis may represent intensity of an output optical signal IOS.

Referring to FIGS. 5 and 6, the output optical signal OOS output from the optoelectronic module 300 may have characteristics of the Relu function. That is, when the intensity of the input optical signal IOS is less than or equal to the threshold value TH, the intensity of the output optical signal OOS may be ‘0’ or an approximate value of ‘0’. When the intensity of the input optical signal IOS exceeds the threshold TH, the intensity of the output optical signal OOS may increase in proportion to the intensity of the input optical signal IOS. The threshold value TH may then be related to the threshold current of the surface emitting laser VCSEL.

In FIG. 6, the intensity of the output optical signal OOS is shown to be related to the intensity of the input optical signal IOS, although the scope of the present disclosure is not so limited. For example, the intensity of the output optical signal OOS may be related to the intensity of the transmission current.

As described above, the graph of the output optical signal OOS output from the optoelectronic module 300 may include one inflection point associated with the threshold current of the surface emitting laser VCSEL.

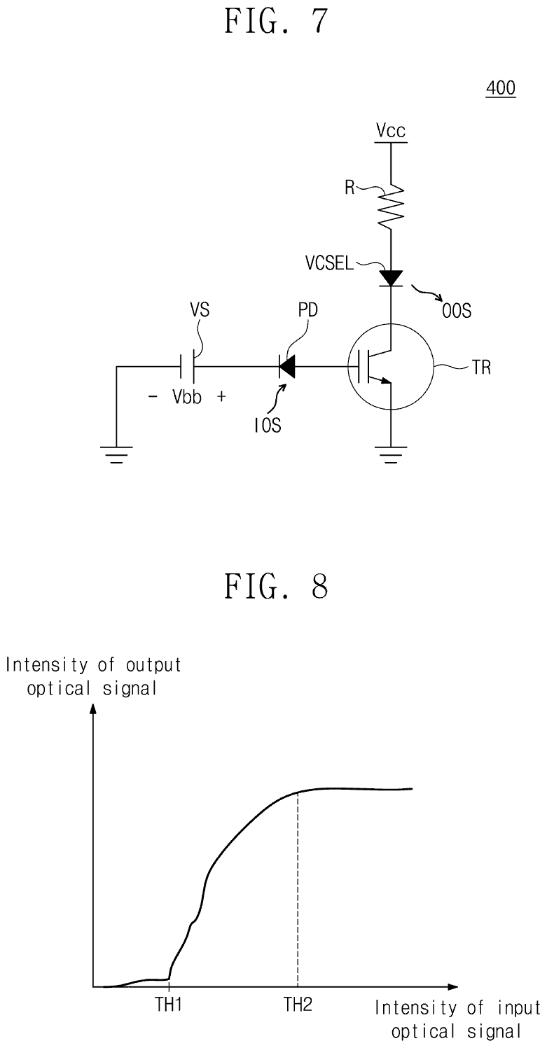

FIG. 7 illustrates a schematic diagram of an optoelectronic module according to an embodiment of the present disclosure. In FIG. 7, an optoelectronic module 400 may correspond to the optoelectronic module 300 in FIG. 5, except that the optoelectronic module 400 further includes a resistor R. That is, a photodiode PD, a transistor TR, and a surface emitting laser VCSEL of the optoelectronic module 400 may respectively correspond to the photodiode PD, the transistor TR and the surface emitting laser VCSEL of the optoelectronic module 300 of FIG. 5. Therefore, redundant description will be omitted.

Referring to FIG. 7, the resistance R may determine a maximum intensity of an output optical signal OOS. For example, the maximum intensity of the output optical signal OOS may be adjusted according to a value of the resistance R.

In some embodiments, the maximum intensity of the output optical signal OOS may be determined based on the resistance R and a voltage Vcc. However, the scope of the present disclosure is not limited thereto.

The optoelectronic module 400 may output the maximum intensity of the output optical signal OOS (referred to hereinafter as ‘maximum value’) as the intensity of the output optical signal OOS.

In some embodiments, the optoelectronic module 400 may output the maximum value as the intensity of the output optical signal OOS based on a transmission current and a threshold current of the surface emitting laser VCSEL. For example, if the transmission current is less than the threshold current of the surface emitting laser VCSEL, the surface emitting Laser VCSEL may not oscillate. In this case, the intensity of the output optical signal OOS may be ‘0’. When the transmission current is greater than the threshold current of the surface emitting laser VCSEL, the surface emitting laser VCSEL may oscillate to output the maximum value as the intensity of the output optical signal OOS. For example, the intensity of the output optical signal OOS may increase according to the intensity of the transmission current until it reaches the maximum value. After reaching the maximum value, the intensity of the output optical signal OOS may be constant as the maximum value.

In some embodiments, the optoelectronic module 400 may output the maximum value as the intensity of the output optical signal OOS based on the intensity of the input optical signal IOS and the threshold current of the surface emitting laser VCSEL.

For example, when the intensity of the input optical signal IOS is less than or equal to a threshold value, the transmission current may be less than the threshold current of the surface emitting laser VCSEL. In this case, the surface emitting laser VCSEL may not oscillate, and the intensity of the output optical signal OOS may be ‘0’. If the intensity of the input optical signal IOS exceeds the threshold value, the transmission current may be greater than the threshold current of the surface emitting laser VCSEL. In this case, the surface emitting laser VCSEL may oscillate to output the maximum value determined by the resistance R as the intensity of the output optical signal OOS. For example, the intensity of the output optical signal OOS may increase according to the intensity of the transmission current until it reaches the maximum value. After reaching the maximum value, the intensity of the output optical signal OOS may be constant as the maximum value.

As described above, the optoelectronic module 400 may output the output optical signal OOS having characteristics of a Sigmoid function among activation functions, based on the intensity of the input optical signal IOS or the transmission current. However, the scope of the present disclosure is not limited thereto, and the optoelectronic module 400 may output the output optical signal OOS having characteristics of various activation functions.

FIG. 8 illustrates a graph of the output optical signal output from the optoelectronic module of FIG. 7. In FIG. 8, a horizontal axis may represent intensity of an input optical signal IOS, and a vertical axis may represent intensity of an output optical signal IOS.

Referring to FIGS. 7 and 8, the output optical signal OOS output from the optoelectronic module 400 may have characteristics of the Sigmoid function. That is, when the intensity of the input optical signal IOS is less than or equal to a first threshold value TH1, the intensity of the output optical signal OOS may be ‘0’ or an approximate value of ‘0’. When the intensity of the input optical signal IOS is greater than the first threshold TH1 and less than or equal to a second threshold TH2, the intensity of the output optical signal OOS may increase based on the intensity of the input optical signal IOS. When the intensity of the input optical signal IOS exceeds the second threshold TH2, the intensity of the output optical signal OOS may correspond to the maximum value. At least one of the first threshold TH1 and the second threshold TH2 may be related to the threshold current of the surface emitting laser VCSEL.

In FIG. 8, the intensity of the output optical signal OOS is shown to be related to the intensity of the input optical signal IOS, although the scope of the present disclosure is not so limited. For example, the intensity of the output optical signal OOS may be related to the intensity of the transmission current.

As described above, the graph of the output optical signal OOS output from the optoelectronic module 400 may include two inflection points associated with the threshold current of the surface emitting laser VCSEL.

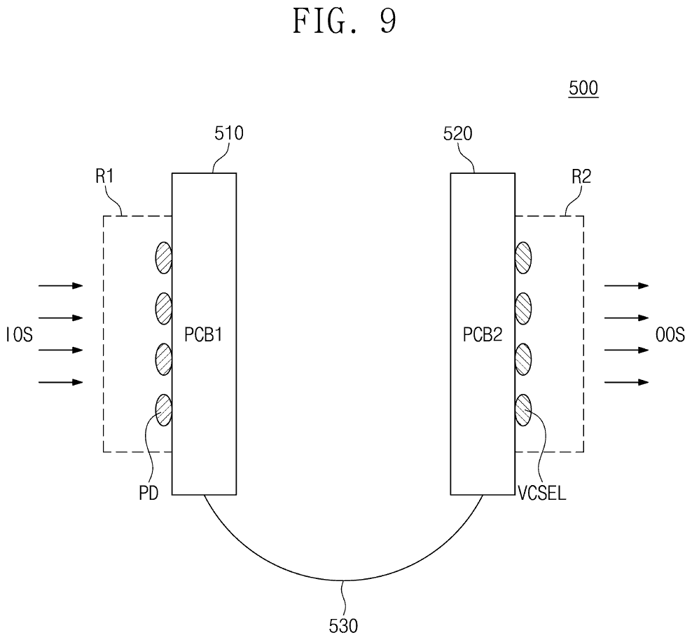

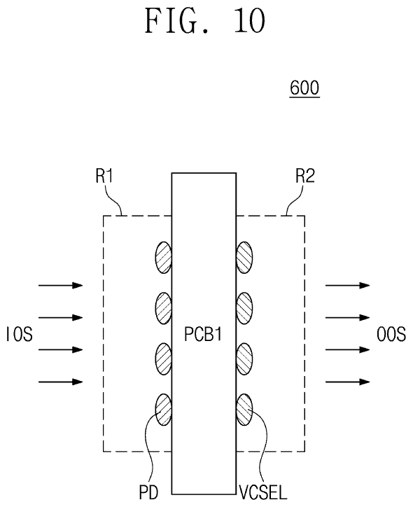

FIG. 9 illustrates a multi-channel optoelectronic module according to an embodiment of the present disclosure. Referring to FIG. 9, a multi-channel optoelectronic module 500 may include a first PCB substrate 510, a second PCB substrate 520, and a connector 530.

The first PCB substrate 510 may include a plurality of photodetectors. For example, the first PCB substrate 510 may include a plurality of photodiodes PDs.

In some embodiments, the plurality of photodiodes PDs may be mounted on the first PCB substrate 510 in a two-dimensional array. For example, a photodetector array composed of the plurality of photodiodes PDs may be disposed in a first region R1 on the first PCB substrate 510. The photodetector array may be in a 4×4 form, but the scope of the present disclosure is not limited thereto, and the photodetector array may be implemented in various forms.

The second PCB substrate 520 may include a plurality of light sources. For example, the second PCB substrate 520 may include a plurality of surface emitting lasers VCSELs.

In some embodiments, the plurality of surface emitting lasers VCSELs may be mounted on the second PCB substrate 520 in a two-dimensional array. For example, a light source array composed of the plurality of surface emitting lasers VCSELs may be disposed in a second region R2 on the second PCB substrate 520. The light source array may be in the form of a 4×4, but the scope of the present disclosure is not limited thereto, and the light source array may be implemented in various forms.

The connector 530 may connect the first PCB substrate 510 and the second PCB substrate 520. The connector 530 may transmit signals between the first PCB substrate 510 and the second PCB substrate 520. For example, the connector 530 may transmit an electrical signal (e.g., current) output from the photodetector array disposed on the first PCB substrate 510 to the second PCB substrate 520.

In some embodiments, the photodetector array and the light source array may be disposed such that propagation direction of the input optical signal IOS and propagation direction of the output optical signal OOS are equal to each other. For example, the first PCB substrate 510 and the second PCB substrate 520 may be disposed in parallel. The photodetector array may be disposed in the first region R1 on the first PCB substrate 510, and the light source array may be disposed the second region R2 on the second PCB substrate 520. However, the scope of the present disclosure is not limited thereto.

In some embodiments, an electronic element such as a transistor TR or operational amplifier may be mounted on the first PCB substrate 510 or the second PCB substrate 520. For example, one or more transistors TRs may be mounted in the first region R1 on the first PCB substrate 510 or the second region R2 on the second PCB substrate 520.

In some embodiments, a transistor TR and a surface emitting laser VCSEL may form a unit cell. A plurality of unit cells may be disposed on the second PCB substrate 520 in an array. For example, a unit cell array composed of the plurality of unit cells may be disposed in the second region R2 on the second PCB substrate 520.

In some embodiments, a resistor R may be mounted on the second PCB substrate 520. For example, one or more resistors Rs may be mounted in the second region R2 on the second PCB substrate 520.

In some embodiments, the transistor TR, the resistor R, and the surface light emitting laser VCSEL may form a unit cell. A plurality of unit cells may be disposed on the second PCB substrate 520 in an array. For example, a unit cell array composed of the plurality of the unit cells may be disposed in the second region R2 on the second PCB substrate 520.

As described above, the multi-channel optoelectronic module 500 can be easily integrated by having a three-dimensional structure.

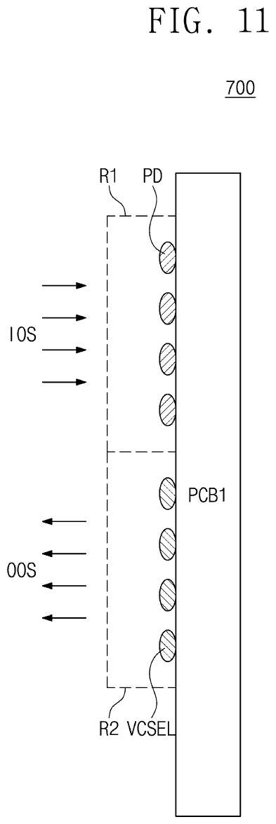

FIG. 10 illustrates a multi-channel optoelectronic module according to an embodiment of the present disclosure.

Referring to FIG. 10, a multi-channel optoelectronic module 600 may be implemented on a first PCB substrate PCB1. The multi-channel optoelectronic module 600 may include a first PCB substrate PCB1 on which a plurality of photodetectors and a plurality of light sources VCSELs are mounted.

In some embodiments, the plurality of photodiodes PDs and the plurality of surface emitting lasers VCSELs may be mounted on the first PCB substrate PCB1 in a two-dimensional array. For example, a photodetector array composed of the plurality of the photodiodes PDs may be disposed in the first region R1 on the first PCB substrate PCB1, and a light source array composed of the plurality of the surface emitting lasers VCSEL may be disposed in the second region R2 on the first PCB board PCB1. That is, the photodetector array and the light source array may be disposed on different sides on the same substrate such that the input optical signal IOS and the output optical signal OOS propagate in the same direction. The photodetector array and the light source array may be in a 4×4 form, but the scope of the present disclosure is not limited thereto, and the photodetector array or the light source array may be implemented in various forms.

In some embodiments, electronic elements such as transistors TRs or operational amplifiers may be mounted on the first PCB substrate PCB1. For example, one or more transistors TRs may be mounted in the first region R1 or the second region R2 on the first PCB substrate PCB1.

In some embodiments, the transistor TR and the surface emitting laser VCSEL may form a unit cell. A plurality of unit cells may be disposed on the first PCB substrate PCB1 in an array form. For example, a unit cell array composed of the plurality of the unit cells may be disposed in the second region R2 on the first PCB substrate PCB1.

In some embodiments, the resistor R may be mounted on the first PCB substrate PCB1. For example, one or more resistors Rs may be mounted in the second region R2 on the first PCB substrate PCB1.

In some embodiments, the transistor TR, the resistor R, and the surface emitting laser VCSEL may form a unit cell. A plurality of unit cells may be disposed on the first PCB substrate PCB1 in an array form. For example, a unit cell array composed of the plurality of the unit cells may be disposed in the second region R2 on the first PCB substrate PCB1.

FIG. 11 illustrates a multi-channel optoelectronic module according to an embodiment of the present disclosure. Referring to FIG. 11, a multi-channel optoelectronic module 700 may be implemented on a first PCB substrate PCB1. The multi-channel optoelectronic module 700 may include a first PCB substrate PCB1 on which a plurality of photodetectors and a plurality of light sources are mounted.

In some embodiments, the plurality of the photodiodes PDs and the plurality of the surface emitting lasers VCSEL may be mounted on the first PCB substrate PCB1 in a two-dimensional array. For example, a photodetector array composed of the plurality of the photodiodes PDs may be disposed in a first region R1 on the first PCB substrate PCB1, and a light source array composed of the plurality of the surface emitting lasers VCSELs may be disposed in a second region R2 on the first PCB board PCB1. That is, the photodetector array and the light source array may be disposed on the same surface on the same substrate such that the input optical signal IOS and the output optical signal OOS propagate in opposite directions to each other. The photodetector array and the light source array may be in the form of a 4×4 array, but the scope of the present disclosure is not limited thereto, and the photodetector array and light source array may be implemented in various array forms.

In some embodiments, electronic elements such as transistors TR or operational amplifiers may be mounted on the first PCB substrate PCB1. For example, one or more transistors TRs may be mounted in the first region R1 or the second region R2 on the first PCB substrate PCB1.

In some embodiments, a resistor R may be mounted on the first PCB substrate PCB1. For example, one or more resistors Rs may be mounted in the first region R1 or the second region R2 on the first PCB substrate PCB1.

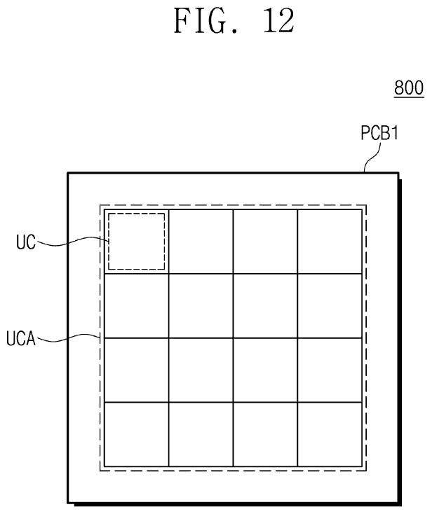

FIG. 12 illustrates a multi-channel optoelectronic module according to an embodiment of the present disclosure. Referring to FIG. 12, a multi-channel optoelectronic module 800 may be implemented as a unit cell array UCA on a first PCB substrate PCB1. The unit cell array UCA may include a plurality of unit cells UCs. Each of the plurality of the unit cells UCs may include a photodiode PD, a transistor TR, and a surface emitting laser VCSEL. In this case, the multi-channel optoelectronic module 800 may output an output optical signal OOS having characteristics of a Relu function among activation functions, based on a input optical signal IOS.

In some embodiments, each of the plurality of the unit cells UC may include a photodiode PD, a transistor TR, a resistor R, and a surface emitting laser VCSEL. In this case, the multi-channel optoelectronic module 800 may output, based on the input optical signal IOS, the output optical signal OOS having characteristics of a Sigmoid function among activation functions.

In some embodiments, the unit cell array UCA may be in the form of a 6×6 array. However, the scope of the present disclosure is not limited thereto, and the unit cell array UCA may be in various array forms.

As described above, the multi-channel optoelectronic module 800 may be implemented as a unit cell array on single PCB substrate so that a process of outputting an output optical signal from an input optical signal may be processed at high speed. In addition, since the multi-channel optoelectronic module 800 is easy to integrate, implementation of an optical artificial neural network system may be easy.

In the above embodiments, components according to the present disclosure are described by using the terms “first”, “second”, “third”, and the like. However, the terms “first”, “second”, “third”, and the like may be used to distinguish components from each other and do not limit the present disclosure. For example, the terms “first”, “second”, “third”, and the like do not involve an order or a numerical meaning of any form.

The above descriptions are detail embodiments for carrying out the present disclosure. Embodiments in which a design is changed simply or which are easily changed may be included in the present disclosure as well as an embodiment described above. In addition, technologies that are easily changed and implemented by using the above embodiments may be included in the present disclosure.

According to the present disclosure, an optoelectronic module may convert a linear input optical signal into a non-linear output optical signal in the form of an activation function and amplify intensity of an optical signal.

According to the present disclosure, an optoelectronic circuit may have a high driving speed by minimizing electronic elements, and may be easily integrated. Therefore, a multi-channel optical artificial neural network system may be easily configured.

According to the present disclosure, the optoelectronic circuit may convert a wavelength of the optical signal, and thus may be utilized as a wavelength converter.

What is claimed is:

1. An optoelectronic module comprising:
a photodetector configured to receive an input light and configured to convert the input light to generate a first current;
an electronic element configured to amplify the first current to generate a second current; and
a light source element configured to convert the second current to generate an output light,
wherein the output light has characteristics of a result of performing a non-linear computation of an optical artificial neural network.

2. The optoelectronic module of claim 1, wherein the non-linear computation includes a computation for applying an activation function, and
wherein the light source element is configured to generate the output light based on the second current and a threshold current of the light source element.

3. The optoelectronic module of claim 2, wherein the activation function is a Relu function, and
wherein the light source element is configured to oscillate such that intensity of the output light is proportional to intensity of the second current when the second current is greater than the threshold current.

4. The optoelectronic module of claim 2, further comprising:
a resistance configured to determine a maximum value of intensity of the output light,
wherein the activation function is a Sigmoid function, and
wherein the light source element is configured to oscillate such that the output light has the intensity corresponding to the maximum value when the second current is greater than the threshold current.

5. The optoelectronic module of claim 2, wherein the photodetector includes a photodiode,
wherein the electronic element includes at least one of a transistor and an operational amplifier, and
wherein the light source element includes a surface emitting laser.

6. The optoelectronic module of claim 5, further comprising:
a unit cell array including a plurality of unit cells,
wherein each of the plurality of unit cells includes the photodetector, the electronic element, and the light source element.

7. The optoelectronic module of claim 6, wherein each of the plurality of unit cells further includes a resistance configured to determine a maximum value of intensity of the output light.

8. The optoelectronic module of claim 5, further comprising:
a photodetector array in which the photodetector is disposed in an array form; and
a light source array in which the light source element is disposed in an array form.

9. The optoelectronic module of claim 8, wherein the photodetector array and the light source array are disposed such that the input light and the output light propagate in the same direction.

10. The optoelectronic module of claim 9, further comprising:
a first PCB substrate including the photodetector array;
a second PCB substrate including the light source array and the electronic element; and
a connector connecting the first PCB substrate and the second PCB substrate.

11. The optoelectronic module of claim 9,
wherein the photodetector array is disposed on a first side of a PCB substrate, and
wherein the light source array is disposed on a second side of the PCB substrate.

12. The optoelectronic module of claim 8,
wherein the photodetector array and the light source array are disposed such that the input light and the output light travel in opposite directions.

13. The optoelectronic module of claim 12,
wherein the photodetector array and the light source array are disposed on a first side of a PCB substrate.

14. An optical artificial neural network system comprising:
a linear computation unit configured to receive an input light including input data and configured to perform a linear computation on the input data to generate a first processed light; and
a non-linear computation unit configured to perform a non-linear computation on data included in the first processed light to generate an output light,
wherein the output light has characteristics of a result of a computation for applying an activation function, and
wherein the non-linear computation unit includes:
a photodetector configured to convert the first processed light to generate a first current;
an electronic element configured to amplify the first current to generate a second current; and
a light source element configured to convert the second current to generate the output light.

15. The optical artificial neural network system of claim 14,
wherein the light source element is configured to generate the output light based on the second current and a threshold current of the light source element.

16. The optical artificial neural network system of claim 15,
wherein the activation function is a Relu function, and
wherein the light source element is configured to oscillate such that intensity of the output light is proportional to intensity of the second current when the second current is greater than the threshold current.

17. The optical artificial neural network system of claim 15,
wherein the non-linear computation unit further includes a resistance configured to determine a maximum value of intensity of the output light,
wherein the activation function is a Sigmoid function, and
wherein the light source element is configured to oscillate such that the output light has the intensity corresponding to the maximum value when the second current is greater than the threshold current.

18. The optical artificial neural network system of claim 15,
wherein the photodetector includes a photodiode, and
wherein the electronic element includes at least one of a transistor and an operational amplifier, and
wherein the light source element includes a surface emitting laser.

19. The optical artificial neural network system of claim 18,
wherein the non-linear computation unit includes a unit cell array including a plurality of unit cells, and
each of the plurality of unit cells includes the photodetector, the electronic element, and the light source element.

20. The optical artificial neural network system of claim 18,
wherein the non-linear computation unit includes:
a photodetector array in which the photodetector is disposed in an array form; and
a light source array in which the light source clement is disposed in an array form.
